(19) United States
(12) Patent Application Publication
(10) Pub. No.: US 2025/0285934 A1
(43) Pub. Date: Sep. 11, 2025

(54) THERMALLY-CONDUCTIVE CRYSTALLINE PEDESTAL FOR SEMICONDUCTOR DEVICE PACKAGES

(71) Applicant: Marvell Asia Pte Ltd, Singapore (SG)

(72) Inventors: Shrinath Shrinivas Ramdas, Agoura Hills, CA (US); Dwayne R. Shirley, Valley Glen, CA (US); Roberto Coccioli, Simi Valley, CA (US)

(21) Appl. No.: 19/073,467

(22) Filed: Mar. 7, 2025

Related U.S. Application Data
(60) Provisional application No. 63/563,298, filed on Mar. 8, 2024.

(51) Int. Cl. H01L 23/373; H01L 23/00; H01L 23/367

(52) U.S. Cl. CPC H01L 23/3735; H01L 23/3675; H01L 23/3732; H01L 23/3738; H01L 24/32; H01L 24/83; H01L 2224/32225; H01L 2224/83191; H01L 2224/83201

(57) ABSTRACT

A semiconductor device package includes a semiconductor die having two opposing faces that define a major plane, wherein the semiconductor die generates heat when in operation. The package includes a packaging lid, contacts, a crystalline pedestal, and a layer of thermal interface material (TIM). The packaging lid encloses the semiconductor die. The contacts are on a first exterior surface of the package parallel to the major plane, the first exterior surface defining a bottom of the package. The crystalline pedestal is formed of one or more crystals having an anisotropic thermal property affecting a thermal conductivity of the pedestal to dissipate the heat generated by the die when in operation, and the pedestal is disposed above the die in thermally-conductive, electrically non-conductive contact with the semiconductor die. The layer of TIM is disposed between the pedestal and the lid, wherein the TIM is thermally conductive and electrically non-conductive.

### CROSS REFERENCE TO RELATED APPLICATION

This disclosure claims the benefit of commonly-assigned U.S. Provisional Patent Application No. 63/563,298, filed Mar. 8, 2024, which is hereby incorporated by reference herein in its entirety.

### FIELD OF USE

This disclosure relates to the packaging of a semiconductor die. More particularly, the disclosure relates to packages and methods, including a semiconductive thermal crystalline pedestal in thermal contact with the semiconductor die.

### BACKGROUND

The background description provided herein is for the purpose of generally presenting the context of the disclosure. Work of the inventors hereof, to the extent the work is described in this background section, as well as aspects of the description that may not otherwise qualify as prior art at the time of filing, are neither expressly nor impliedly admitted to be prior art against the subject matter of the present disclosure.

A semiconductor device includes a semiconductor die on which the device circuits are formed. Typically, the semiconductor die is protected by packaging (including, e.g., a packaging lid). Within the semiconductor device package, the semiconductor die may be mounted on a supporting substrate with conductive interconnections. Leads connected to terminals of the semiconductor die are coupled to contacts on the outside of the semiconductor device package. The contacts may take the form of rigid metallic pins or, alternatively, conductive bumps or solder balls. The semiconductor die may be completely enclosed in the semiconductor device package, or one surface (e.g., where the semiconductor die is a rectangular solid, one of the two largest surfaces) may be exposed. The semiconductor device package should allow for dissipation of heat generated by the semiconductor die when in operation.

### SUMMARY

In accordance with implementations of the subject matter of this disclosure, a semiconductor device package including a semiconductor die having two opposing faces that define a major place, wherein the semiconductor die generates heat when in operation, a packaging lid enclosing the semiconductor die, a plurality of contacts on a first exterior surface of the semiconductor device package that is parallel to the major plane, the first exterior surface defining a bottom of the semiconductor device package, a crystalline pedestal formed of one or more crystals having an anisotropic thermal property affecting a thermal conductivity of the crystalline pedestal to dissipate the heat generated by the semiconductor die when in operation, the crystalline pedestal disposed above the semiconductor die in thermally-conductive, electrically non-conductive contact with the semiconductor die, and a first layer of a thermal interface material disposed between the pedestal and the packaging lid, wherein the thermal interface material is thermally conductive and electrically non-conductive.

In a first implementation of such a semiconductor device package, the semiconductor device package may further include a substrate layer below the semiconductor die and forming the first exterior surface.

In a second implementation of such a semiconductor device package, the semiconductor device package may further include a second layer of the thermal interface material disposed between (i) the semiconductor die and (ii) the crystalline pedestal, wherein the second layer of the thermal interface material is configured to promote transfer of the heat from the semiconductor die to the crystalline pedestal.

In a third implementation of such a semiconductor device package, the one or more crystals of the crystalline pedestal may be oriented to dissipate the heat in a direction extending from the semiconductor die toward the packaging lid.

According to a first aspect of that third implementation, the one or more crystals of the crystalline pedestal may be oriented in a 111 crystallographic direction.

In a fourth implementation of such a semiconductor device package, heat-producing circuitry of the semiconductor die may be in close thermal contact with the crystalline pedestal.

In a fifth implementation of such a semiconductor device package, the crystalline pedestal may include a single crystal diamond (SCD).

In a sixth implementation of such a semiconductor device package, the crystalline pedestal may include silicon carbide (Sic) and one or more through-silicon vias (TSVs) disposed within the silicon carbide, wherein each of the one or more through-silicon vias extends in a direction perpendicular to the major plane.

In accordance with implementations of the subject matter of this disclosure, a method of fabricating a semiconductor device package including a semiconductor die having two opposing surfaces that define a major plane, the method including placing a crystalline pedestal formed of one or more crystals having an anisotropic thermal property above the semiconductor die in thermally conductive, electrically non-conductive contact with a first surface of the semiconductor die, wherein the anisotropic thermal property affects a thermal conductivity of the crystalline pedestal to dissipate heat from the semiconductor die, depositing a first layer of a thermal interface material onto a top surface, opposite from the first surface of the semiconductor die, of the crystalline pedestal, wherein the thermal interface material is thermally conductive and electrically non-conductive, and enclosing at least the semiconductor die, the first layer of the thermal interface material and the pedestal, perpendicular to the major plane, with a packaging lid, wherein the packaging lid is in thermal contact with the first layer of the thermal interface material to promote heat transfer from the crystalline pedestal, through the first layer of the thermal interface material, to the packaging lid.

In a first implementation of such a method may further include placing a substrate layer adjacent a second surface of the semiconductor die parallel to the major plane and opposite the first surface of the semiconductor die.

In a second implementation of such a method may further include depositing a second layer of the thermal interface material between (i) the semiconductor die and (ii) the crystalline pedestal to promote transfer of the heat from the semiconductor die to the crystalline pedestal.

In a third implementation of such a method, placing the crystalline pedestal may include aligning the crystalline pedestal such that the one or more crystals of the crystalline pedestal is oriented to dissipate the heat in a direction extending from the semiconductor die toward the packaging lid.

According to a first aspect of that third implementation, the placing the crystalline pedestal may include aligning the crystalline pedestal such that the one or more crystals of the crystalline pedestal is oriented in a 111 crystallographic direction.

In a fourth implementation of such a method may further include thinning the semiconductor die in a direction perpendicular to the major plane to reduce an amount of semiconductor material of the semiconductor die between heat-producing circuitry and the crystalline pedestal.

In a fifth implementation of such a method, placing the crystalline pedestal above the semiconductor die may include placing a single crystal diamond above the semiconductor die.

In a sixth implementation of such a method, placing the crystalline pedestal above the semiconductor die may include placing the crystalline pedestal including silicon carbide, and one or more through-silicon vias disposed within the silicon carbide wherein each of the one or more through-silicon vias extends in a direction perpendicular to the major plane.

In accordance with implementations of the subject matter of this disclosure, a crystalline pedestal for use within a semiconductor device package including a semiconductor die having two opposing faces that define a major plane, a packaging lid enclosing the semiconductor die, a plurality of contacts on a first exterior surface of the semiconductor device package that is parallel to the major plane, the first exterior surface defining a bottom of the semiconductor device package, and a first layer of a thermal interface material disposed between the crystalline pedestal and the packaging lid, wherein the thermal interface material is thermally conductive and electrically non-conductive, the crystalline pedestal including one or more crystals having an anisotropic thermal property that affects a thermal conductivity of the crystalline pedestal to dissipate heat generated by the semiconductor die when in operation, wherein the crystalline pedestal is disposed above the semiconductor die in thermally-conductive, electrically non-conductive contact with the semiconductor die.

In a first implementation of such a crystalline pedestal, the one or more crystals of the crystalline pedestal may be oriented to dissipate the heat in a direction extending from the semiconductor die toward the packaging lid.

According to a first aspect of that first implementation, the one or more crystals of the crystalline pedestal may be oriented in a 111 crystallographic direction.

In accordance with implementations of the subject matter of this disclosure, a method for conducting heat from a semiconductor die having two opposing surfaces that define a major plane, the method including aligning a crystalline pedestal, formed of one or more crystals having an anisotropic thermal property that affects a thermal conductivity of the crystalline pedestal, above the semiconductor die in thermally conductive, electrically non-conductive contact with a first surface of the semiconductor die, to dissipate the heat from the semiconductor die, depositing a first layer of a thermal interface material onto a top surface, opposite from the first surface of the semiconductor die, of the crystalline pedestal, wherein the thermal interface material is thermally conductive and electrically non-conductive, and enclosing at least the semiconductor die, the first layer of the thermal interface material and the pedestal, perpendicular to the major plane, with a packaging lid, wherein the packaging lid is in thermal contact with the first layer of the thermal interface material to promote heat transfer from the crystalline pedestal, through the first layer of the thermal interface material, to the packaging lid.

In a first implementation of such a method, aligning the crystalline pedestal may include aligning the crystalline pedestal such that the one or more crystals of the crystalline pedestal is oriented in a 111 crystallographic direction.

### BRIEF DESCRIPTION OF THE DRAWINGS

Further features of the disclosure, its nature, and various advantages, will be apparent upon consideration of the following detailed description, taken in conjunction with the accompanying drawings, in which like reference characters refer to like parts throughout, and in which:

FIG. 1 is a vertical cross-sectional view of a semiconductor device package in accordance with implementations of the subject matter of this disclosure;

FIG. 2 is a vertical cross-sectional view of another semiconductor device package with TSVs in accordance with implementations of the subject matter of this disclosure;

FIG. 3 is a vertical cross-sectional view of another semiconductor device package with a single crystal diamond in accordance with implementations of the subject matter of this disclosure; and

FIG. 4 is a flow diagram of a method of fabricating a semiconductor device package in accordance with implementations of the subject matter of this disclosure.

### DETAILED DESCRIPTION

As noted above, a semiconductor die generates heat when in operation, and the package should allow for heat dissipation (e.g., to reduce or avoid hot spots and reduce thermal risk for the die). Moreover, semiconductor dies come in different sizes, including different thicknesses, and it may be advantageous to be able to accommodate different sizes of semiconductor dies in a limited number of semiconductor device package form factors.

The foregoing objectives may be met, in accordance with implementations of the subject matter of this disclosure, by providing (e.g., in a semiconductor device package) a crystalline pedestal formed of one or more crystals having an anisotropic thermal property which is positioned in a thermally conductive, but electrically nonconductive relationship with the semiconductor die. In addition to serving as a spacer to conform the semiconductor die to a particular semiconductor device package dimension—which may be determined by the dimensions of an apparatus in which the semiconductor device package may be used, or by dimensions of available semiconductor device packages—the crystalline pedestal aids in dissipating, to the ambient environment, heat generated by operation of the semiconductor die. In some implementations, the crystalline pedestal dissipates heat to the ambient environment surrounding the semiconductor device package through thermal interface material (TIM) and a packaging lid of the semiconductor device package.

The crystalline pedestal positioned above the semiconductor die (considering the substrate of the semiconductor device package to be the bottom) is formed of one or more crystals having an anisotropic thermal property. The anisotropic thermal property of the crystalline pedestal affects thermal conductivity of the crystalline pedestal and the direction of the thermal conductivity (e.g., the direction of heat transfer through the crystalline pedestal). The thermal conductivity of the crystalline pedestal is determinative of the heat dissipation of the crystalline pedestal from the semiconductor die to the ambient environment surrounding the semiconductor device package. In some implementations, the number of crystals, the orientation of each crystal of the crystalline pedestal, and whether the crystalline pedestal includes through-silicon vias (TSVs) may be determined, at least in part, based on the thermal conductivity needed for a respective application of the semiconductor device package. The specific thermal conductivity required for a particular implementation may depend on the expected running temperature of the active semiconductor die and may be determined by simulation or experimentation.

In addition to having certain anisotropic thermal properties, the crystalline pedestal may be made of a single crystal (e.g., single crystal diamond (SCD)) or more than one crystal (e.g., silicon carbide with TSVs). In some implementations, the TSVs disposed in the silicon carbide may be filled with copper or any other suitable thermally-conductive material to promote heat dissipation from the semiconductor die to the packaging lid of the semiconductor device package.

In some implementations, each of the crystals of the crystalline pedestal is oriented to promote heat dissipation from the semiconductor die to the ambient environment surrounding the semiconductor device package. The orientation of each crystal of the crystalline pedestal may be referred to by, for example, a Miller index. A Miller index is a set of three integers (e.g., <hkl>) that may be used to denote an orientation of a respective crystal plane in a lattice, based on intercepts that the crystal plane makes with the crystallographic axes. For example, a Miller index of <hkl> includes h—the intercept with the x-axis, k—the intercept with the y-axis, and l—the intercept with the z-axis. A particular thermal conductivity of the crystalline pedestal may be achieved by modifying the orientation of each respective crystal of the crystalline pedestal, causing to change the anisotropic thermal property of the crystalline pedestal. The anisotropic thermal property of the crystalline pedestal determines, in part, the thermal conductivity of the crystalline pedestal and the direction of the thermal conductivity (e.g., the direction of heat transfer through the crystalline pedestal). In some implementations, each crystal of the crystalline pedestal is oriented in a <111> crystallographic direction to provide the desired thermal conductivity of the crystalline pedestal. In some implementations, when the crystalline pedestal is made of an SCD, a top surface (e.g., the surface in thermal contact with the TIM layer) is oriented in a <110> crystallographic direction to provide the desired thermal conductivity of the crystalline pedestal. When the crystalline pedestal is made of an SCD, the thermal conductivity is highest along the <111> crystallographic direction due to the efficient propagation of phonons along this crystallographic direction. The <111> crystallographic direction may be defined as the direction extending from one corner of the crystal to the opposite corner, extending through the volumetric center of the crystal.

The semiconductor device package also includes the packaging lid, which is configured to enclose the semiconductor die, contacts (e.g., an array of bumps, balls, or any other suitable contacts), one or more TIM layers positioned within the semiconductor device package, and the crystalline pedestal.

The crystalline pedestal should be in thermal contact with the semiconductor die to dissipate heat, but, as noted, should be in an electrically non-conductive contact with the semiconductor die. In one implementation, a TIM, configured to establish a thermally conductive continuum in such implementation, may be disposed between the semiconductor die and the crystalline pedestal. Each layer of TIM positioned within the semiconductor device package should be thermally conductive but electrically non-conductive. Suitable materials that may be used as the TIM include, but are not limited to, silicone adhesives and epoxy adhesives.

The crystalline pedestal should also be in thermal contact with the packaging lid (if any), configured to enclose the semiconductor die, to promote heat dissipation from the crystalline pedestal to the packaging lid. However, in one implementation, the semiconductor device package further includes a layer of TIM positioned between the crystalline pedestal and the packaging lid.

In a semiconductor device package implemented with an SCD, there will be TIM positioned between the semiconductor die and the packaging lid, while the SCD will be in direct thermal contact with the semiconductor die. However, in a semiconductor device package implemented with more than one crystal (e.g., SiC crystals), there may also be TIM positioned between the semiconductor die and the crystalline pedestal, to promote heat transfer from the semiconductor die to the crystalline pedestal.

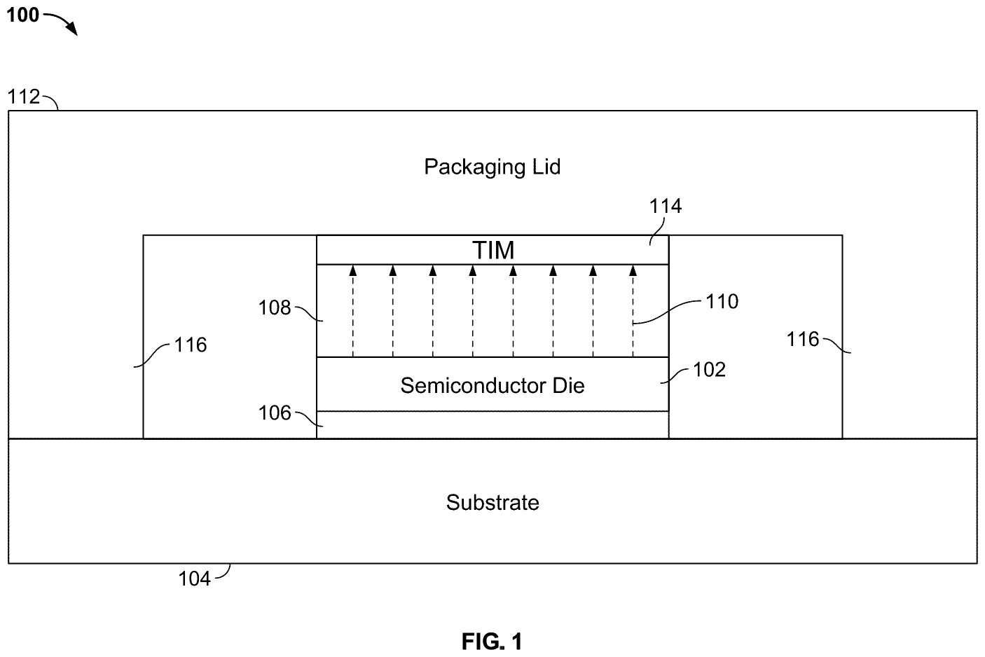

The subject matter of this disclosure may be better understood by reference to FIGS. 1-4.

FIG. 1 is a cross-sectional view of a semiconductor device package 100 according to an implementation of the subject matter of this disclosure. Package 100 includes a crystalline pedestal 108 disposed onto a semiconductor die 102 and the semiconductor die 102 separated from a substrate 104 by contacts 106. Electrical conductivity between semiconductor die 102 and substrate 104 is afforded by contacts 106 or by any other suitable conductive interconnects, which may have cylindrical, spherical, or other suitable shapes. In some implementations, contacts 106 may be formed from a metal such as copper. Contacts 106, or other suitable connectivity structures, may be used to connect circuit components (not shown) on semiconductor die 102 to exterior package contacts. The package contacts may be pins (not shown), an array of bumps (i.e., a bump array; not shown), or solder balls (i.e., a ball-grid array; not shown). The connections between circuit components on semiconductor die 102 and contacts 106, and between contacts 106 and package contacts, are not explicitly shown.

Package 100 further includes a packaging lid 112 that protects the internal elements of package 100. In some implementations, packaging lid 112 is a lid formed from a thermally-conductive material. In some implementations of this disclosure, the content of package 100 may be completely covered (e.g., by packaging lid 112). In an enclosed-die package, packaging lid 112 may be integrated with the enclosure or may be a separate lid. The packaging lid 112 may be formed to leave a void that corresponds to the volume of the package contents, as described below.

If packaging lid 112 is metallic, the metallic lid may be stamped or machined to leave a void of a specific height in package 100. The specific height may be the total height of contacts 106, semiconductor die 102, crystalline pedestal 108, and thermal interface material (TIM) 114 in which packaging lid 112 would be flush with a top surface of the TIM 114. In some embodiments, packaging lid 112 (as shown) may have a downward extension 116 that rests on substrate 104.

The total height of package 100 is determined by the combined thicknesses of the various layers of package 100 including the thickness of substrate 104, the thickness of contacts 106, the thickness of semiconductor die 102, the thickness of crystalline pedestal 108, and the thickness of TIM 114. The thickness of semiconductor die 102 may be determined at least in part by the circuitry to be formed in semiconductor die 102, which in turn is determined by the intended function of semiconductor die 102. The thickness of substrate 104 is determined at least in part by the number of layers, which may be a function of electrical requirements, performance requirements, component density, etc.

The thickness of crystalline pedestal 108 may be determined at least in part by an anisotropic thermal property 110 of the crystals used to form the crystalline pedestal 108, and the heat to be dissipated, based on the operating temperature of the circuitry on semiconductor die 102. The anisotropic thermal property 110 of the crystals used to form the crystalline pedestal 108 affects a direction of the transfer of heat through the crystalline pedestal 108, and thus affects the thermal conductivity of the crystalline pedestal 108. Therefore, each respective crystal of the crystalline pedestal 108 may be oriented based on the respective anisotropic thermal property 110 of the respective crystal to change the direction of heat transfer and to modify the thermal conductivity of the crystalline pedestal 108. For example, in an application in which a particular region of semiconductor die 102 runs relatively hotter than other regions of semiconductor die 102, then the respective crystals closer to the particular region (e.g., in one implementation) are oriented towards the hot spot region so as to provide a directed channel that allows heat to more easily flow away from the particular region. In some implementations, the target size of the overall package 100 also may factor into the thickness of pedestal 108. In some implementations of the subject matter of this disclosure, the thickness of pedestal 108 may be selected to fill the void, described above, inside package 100 left by a standard packaging lid 112 that has a predetermined height dimension. A semiconductor device package (e.g., semiconductor device package 100) may be assembled with a standard package size and standard package dimensions, including a standard package height. Such semiconductor device packages (e.g., package 100) may include semiconductor dies 102 of varying thicknesses, therefore leaving varying void sizes to be filled by one or more internal elements of the package 100, such as crystalline pedestal 108 and TIM 114. Therefore, in some implementations, the height of a standard crystalline pedestal 108 may be adapted to fit such a standard packaging lid 112 and provide a thermally conductive continuum, in combination with TIM 114, by selectively adapting the pedestal thickness, such as by grinding or other techniques for physically altering the pedestal thickness.

Crystalline pedestal 108 is designed and oriented to exhibit favorable thermally conductive properties to draw heat away from the semiconductor die 102 when semiconductor die 102 is in operation. In some implementations, crystalline pedestal 108 is made of a single crystal (e.g., SCD), multiple crystals (e.g., SiC with TSVs), or any suitable carbon-based crystals.

As there should be good thermal contact, but not electrical contact, between semiconductor die 102 and crystalline pedestal 108 for the pedestal 108 to serve its function of conducting heat away from semiconductor die 102, a further layer of TIM (not shown in FIG. 1), which is thermally conductive, but electrically non-conductive, is provided between semiconductor die 102 and crystalline pedestal 108.

The crystalline pedestal 108 should also be in thermal contact with packaging lid 112, configured to enclose the semiconductor die 102, to promote heat dissipation from the crystalline pedestal 108 to the packaging lid 112. The semiconductor device package 100 further includes a layer of TIM 114 positioned between the crystalline pedestal 108 and the packaging lid 112 to ensure such thermal contact between the crystalline pedestal 108 and packaging lid 112 of package 100, allowing heat to be conducted from pedestal 108 to packaging lid 112 of package 100, which then conducts or radiates the heat to the ambient environment. As previously noted, a suitable thermally conductive, electrically non-conductive, material to serve as TIM (e.g., TIM 114) may be silicone adhesive or an epoxy adhesive.

The inclusion of crystalline pedestal 108 according to an implementation of the subject matter of this disclosure allows the provision of semiconductor device packages (e.g., semiconductor device package 100) with uniform heights notwithstanding differences in the semiconductor die thickness, by adjusting the thickness of crystalline pedestal 108 to adjust the overall package height.

In addition to the thermal benefits of including crystalline pedestal 108, the presence of pedestal 108 allows semiconductor die 102 to be thinner than if there were no pedestal 108. In some implementations, semiconductor die 102 may be thinned to remove semiconductor material of the semiconductor die 102 between heat-producing circuitry and the crystalline pedestal 108. The combination of the two thinner layers of crystalline pedestal 108 and semiconductor die 102, separated by an additional TIM layer (not shown in FIG. 1), also may reduce mechanical stress on semiconductor die 102 caused by contacts 106.

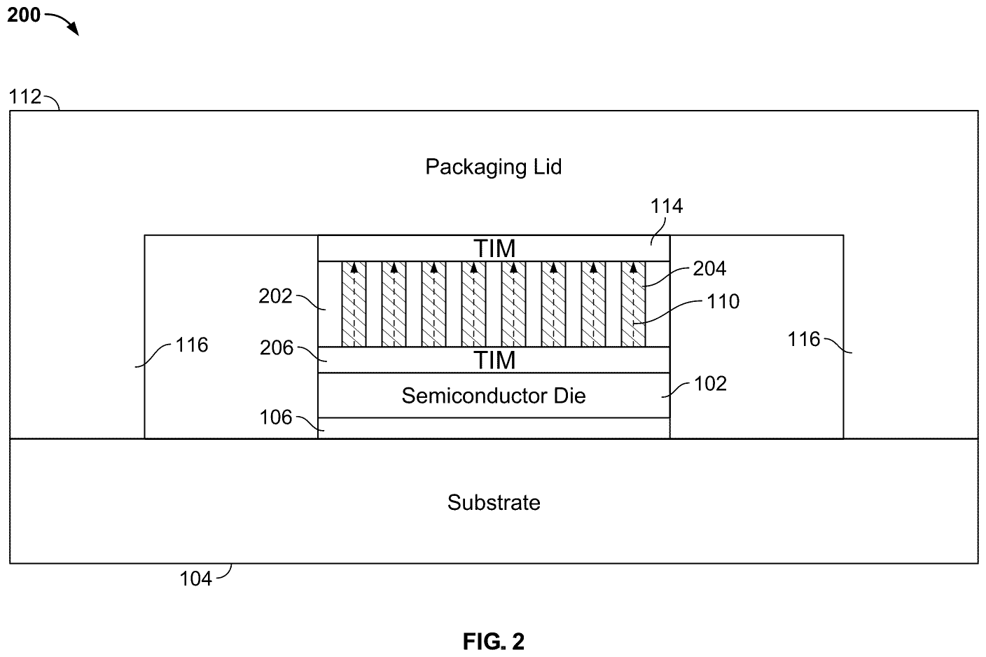

FIG. 2 is a vertical cross-sectional view of another semiconductor device package 200 with multiple crystals 202 (e.g., SiC) and TSVs 204 in accordance with implementations of the subject matter of this disclosure. In some implementations the TSVs 204 disposed in the crystals 202 (e.g., SiC) may be filled with copper or any other suitable thermally-conductive material to promote heat dissipation from the semiconductor die 102 to the packaging lid 112 of the semiconductor device package 200. In one implementation, the TSVs 204 may be located substantially above hotter running regions of the semiconductor die 102. In another implementation, the TSVs 204 are uniformly distributed in the crystals 202, as shown in FIG. 2.

In such a semiconductor device package 200 implemented with more than one crystal 202 (e.g., SiC crystal), there may also be TIM 206 positioned between (a) semiconductor die 102 and (b) the crystalline pedestal (e.g., crystals 202 and TSVs 204), to promote heat transfer from the semiconductor die 102 to the crystalline pedestal (e.g., crystals 202 and TSVs 204).

The crystalline pedestal (e.g., crystals 202 and TSVs 204) should also be in thermal contact with packaging lid 112, which is configured to enclose the semiconductor die 102, to promote heat dissipation from the crystalline pedestal (e.g., crystals 202 and TSVs 204) to the packaging lid 112. Similar to semiconductor device package 100 of FIG. 1, semiconductor device package 200 further includes a layer of TIM 114 positioned between the crystalline pedestal (e.g., crystals 202 and TSVs 204) and the packaging lid 112. This promotes heat transfer from the crystalline pedestal (e.g., crystals 202 and TSVs 204) to the packaging lid 112 which then conducts or radiates the heat to the ambient environment.

In some implementations, the thickness of each TSV 204 may be around 10 μm to 50 μm. However, the thickness of each TSV 204 included in crystals 202 (e.g., SiC crystals) may be based on factors such as the size (e.g., the thickness) of the crystals 202, a desired thermal performance (e.g., desired thermal conductivity), and the manufacturing process used to fabricate the semiconductor device package 200.

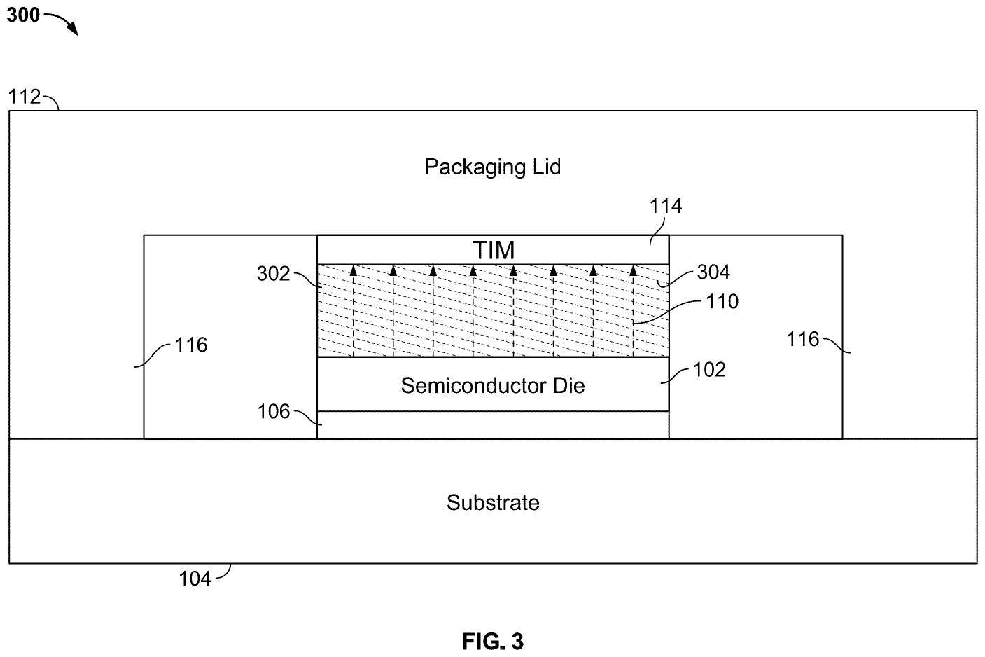

FIG. 3 is a vertical cross-sectional view of another semiconductor device package 300 with an SCD 302 of a crystallographic orientation 304 in accordance with implementations of the subject matter of this disclosure.

Similarly to semiconductor device package 100 in FIG. 1, semiconductor device package 300 implemented with SCD 302 includes TIM 114 between SCD 302 and the packaging lid 112, while SCD 302 will be in direct thermal contact with the semiconductor die 102.

In accordance with implementations of the present disclosure, SCD 302 is oriented to promote heat dissipation from semiconductor die 102 to the ambient environment surrounding the semiconductor device package 300. A particular thermal conductivity of the SCD 302 may be achieved by modifying the orientation 304 of SCD 302. For example, SCD 302 shown in FIG. 3 is oriented in a <111> crystallographic direction to establish the anisotropic thermal property 110 and provide the desired thermal conductivity of the SCD 302. In one implementation, the SCD 302 can be oriented to draw heat from one or more particular regions of semiconductor die 102 that runs hotter relative to other regions of semiconductor die 102.

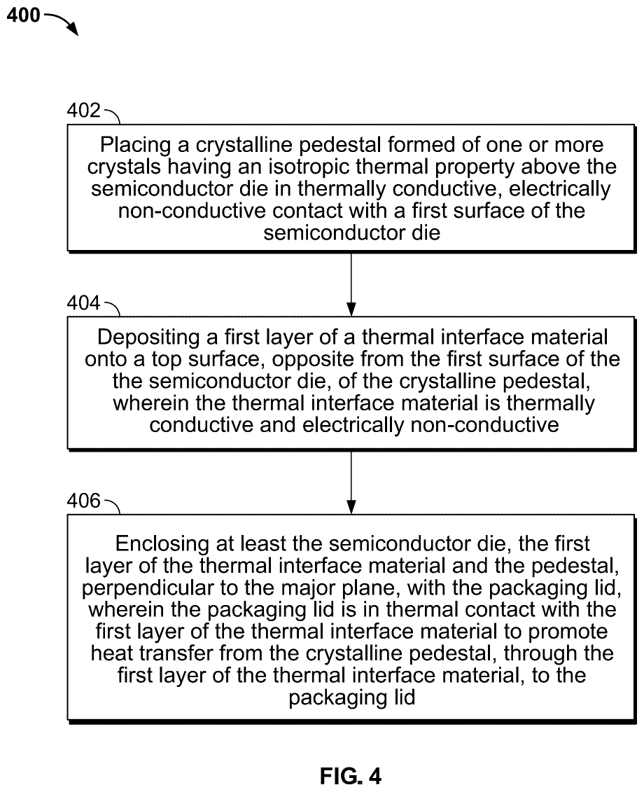

Method 400 in accordance with implementations of the subject matter of this disclosure for fabricating a semiconductor device package is diagrammed in FIG. 4. At 402, a crystalline pedestal formed of one or more crystals having an anisotropic thermal property is placed above the semiconductor die to be in thermally conductive, electrically non-conductive contact with a first surface of the semiconductor die. At 404, a first layer of a thermal interface material is deposited onto a top surface (e.g., the major face opposite from the first surface of the semiconductor die) of the crystalline pedestal, wherein the thermal interface material is thermally conductive and electrically non-conductive. At 406, at least the semiconductor die, the first layer of the thermal interface material, and the pedestal are enclosed with the packaging lid, perpendicular to the major plane, wherein the packaging lid is in thermal contact with the thermal interface layer to promote heat transfer from the crystalline pedestal, through the thermal interface material, to the packaging lid. Method 400 then ends.

Thus it is seen that a semiconductor device package is provided with a crystalline pedestal formed of at least one crystal having an anisotropic thermal property, which promotes the dissipation of heat generated by the semiconductor die when in operation.

As used herein and in the claims which follow, the construction “one of A and B” shall mean “A or B.”

It is noted that the foregoing is only illustrative of the principles of the invention, and that the invention can be practiced by other than the described embodiments, which are presented for purposes of illustration and not of limitation, and the present invention is limited only by the claims which follow.

What is claimed is:

1. A semiconductor device package comprising:
a semiconductor die having two opposing faces that define a major plane, wherein the semiconductor die generates heat when in operation;
a packaging lid enclosing the semiconductor die;
a plurality of contacts on a first exterior surface of the semiconductor device package that is parallel to the major plane, the first exterior surface defining a bottom of the semiconductor device package;
a crystalline pedestal formed of one or more crystals having an anisotropic thermal property affecting a thermal conductivity of the crystalline pedestal to dissipate the heat generated by the semiconductor die when in operation, the crystalline pedestal disposed above the semiconductor die in thermally-conductive, electrically non-conductive contact with the semiconductor die; and
a first layer of a thermal interface material disposed between the pedestal and the packaging lid, wherein the thermal interface material is thermally conductive and electrically non-conductive.

2. The semiconductor device package of claim 1, further comprising a substrate layer below the semiconductor die and forming the first exterior surface.

3. The semiconductor device package of claim 1, further comprising:
a second layer of the thermal interface material disposed between (i) the semiconductor die and (ii) the crystalline pedestal, wherein the second layer of the thermal interface material is configured to promote transfer of the heat from the semiconductor die to the crystalline pedestal.

4. The semiconductor device package of claim 1, wherein the one or more crystals of the crystalline pedestal is oriented to dissipate the heat in a direction extending from the semiconductor die toward the packaging lid.

5. The semiconductor device package of claim 4, wherein the one or more crystals of the crystalline pedestal is oriented in a 111 crystallographic direction.

6. The semiconductor device package of claim 1, wherein heat-producing circuitry of the semiconductor die is in close thermal contact with the crystalline pedestal.

7. The semiconductor device package of claim 1, wherein the crystalline pedestal comprises a single crystal diamond.

8. The semiconductor device package of claim 1, wherein the crystalline pedestal comprises:
silicon carbide; and
one or more through-silicon vias disposed within the silicon carbide, wherein each of the one or more through-silicon vias extends in a direction perpendicular to the major plane.

9. A method of fabricating a semiconductor device package comprising a semiconductor die having two opposing surfaces that define a major plane, the method comprising:
placing a crystalline pedestal formed of one or more crystals having an anisotropic thermal property above the semiconductor die in thermally conductive, electrically non-conductive contact with a first surface of the semiconductor die, wherein the anisotropic thermal property affects a thermal conductivity of the crystalline pedestal to dissipate heat from the semiconductor die;
depositing a first layer of a thermal interface material onto a top surface, opposite from the first surface of the semiconductor die, of the crystalline pedestal, wherein the thermal interface material is thermally conductive and electrically non-conductive; and
enclosing at least the semiconductor die, the first layer of the thermal interface material and the pedestal, perpendicular to the major plane, with a packaging lid, wherein the packaging lid is in thermal contact with the first layer of the thermal interface material to promote heat transfer from the crystalline pedestal, through the first layer of the thermal interface material, to the packaging lid.

10. The method of fabricating a semiconductor device package according to claim 9, the method further comprising placing a substrate layer adjacent a second surface of the semiconductor die parallel to the major plane and opposite the first surface of the semiconductor die.

11. The method of fabricating a semiconductor device package according to claim 9, the method further comprising depositing a second layer of the thermal interface material between (i) the semiconductor die and (ii) the crystalline pedestal to promote transfer of the heat from the semiconductor die to the crystalline pedestal.

12. The method of fabricating a semiconductor device package according to claim 9, wherein the placing the crystalline pedestal comprises aligning the crystalline pedestal such that the one or more crystals of the crystalline pedestal is oriented to dissipate the heat in a direction extending from the semiconductor die toward the packaging lid.

13. The method of fabricating a semiconductor device package according to claim 12, wherein the placing the crystalline pedestal comprises aligning the crystalline pedestal such that the one or more crystals of the crystalline pedestal is oriented in a 111 crystallographic direction.

14. The method of fabricating a semiconductor device package according to claim 9, the method further comprising thinning the semiconductor die in a direction perpendicular to the major plane to reduce an amount of semiconductor material of the semiconductor die between heat-producing circuitry and the crystalline pedestal.

15. The method of fabricating a semiconductor device package according to claim 9, wherein placing the crystalline pedestal above the semiconductor die comprises placing a single crystal diamond above the semiconductor die.

16. The method of fabricating a semiconductor device package according to claim 9, wherein placing the crystalline pedestal above the semiconductor die comprises placing the crystalline pedestal comprising:
silicon carbide; and
one or more through-silicon vias disposed within the silicon carbide wherein each of the one or more through-silicon vias extends in a direction perpendicular to the major plane.

17. A crystalline pedestal for use within a semiconductor device package including a semiconductor die having two opposing faces that define a major plane, a packaging lid enclosing the semiconductor die, a plurality of contacts on a first exterior surface of the semiconductor device package that is parallel to the major plane, the first exterior surface defining a bottom of the semiconductor device package, and a first layer of a thermal interface material disposed between the crystalline pedestal and the packaging lid, wherein the thermal interface material is thermally conductive and electrically non-conductive, the crystalline pedestal comprising:
one or more crystals having an anisotropic thermal property that affects a thermal conductivity of the crystalline pedestal to dissipate heat generated by the semiconductor die when in operation; wherein:
the crystalline pedestal is disposed above the semiconductor die in thermally-conductive, electrically non-conductive contact with the semiconductor die.

18. The crystalline pedestal of claim 17, wherein the one or more crystals of the crystalline pedestal are oriented to dissipate the heat in a direction extending from the semiconductor die toward the packaging lid.

19. The crystalline pedestal of claim 18, wherein the one or more crystals of the crystalline pedestal is oriented in a 111 crystallographic direction.

20. A method for conducting heat from a semiconductor die having two opposing surfaces that define a major plane, the method comprising:
aligning a crystalline pedestal, formed of one or more crystals having an anisotropic thermal property that affects a thermal conductivity of the crystalline pedestal, above the semiconductor die in thermally conductive, electrically non-conductive contact with a first surface of the semiconductor die, to dissipate the heat from the semiconductor die;
depositing a first layer of a thermal interface material onto a top surface, opposite from the first surface of the semiconductor die, of the crystalline pedestal, wherein the thermal interface material is thermally conductive and electrically non-conductive; and
enclosing at least the semiconductor die, the first layer of the thermal interface material and the pedestal, perpendicular to the major plane, with a packaging lid, wherein the packaging lid is in thermal contact with the first layer of the thermal interface material to promote heat transfer from the crystalline pedestal, through the first layer of the thermal interface material, to the packaging lid.

21. The method of for conducting heat from the semiconductor die according to claim 20, wherein aligning the crystalline pedestal comprises aligning the crystalline pedestal such that the one or more crystals of the crystalline pedestal is oriented in a 111 crystallographic direction.
